(19) United States
(12) Patent Application Publication
(10) Pub. No.: US 2005/0102432 A1
(43) Pub. Date: May 12, 2005

(54) Legacy keyboard support system

(76) Inventor: Charles H. Winslow, Scottsdale, AZ (US)

Correspondence Address: JOSEPH W MOTT;JENNINGS STROUSS & SALMON PLC, 201 EAST WASHINGTON STREET, 11TH FLOOR, PHOENIX, AZ, 85004-2385, US

(21) Appl. No.: 09/900,581

(22) Filed: Jul. 5, 2001

(51) Int. Cl. H03M 11/00; H03K 17/94

(52) U.S. Cl. 710/1; 341/26; 341/22

(57) ABSTRACT

A system and method for using a nonstandard keyboard attached to the client in a client-server network is disclosed. A keyboard driver and filter intercepts the nonstandard scan codes and converts them to unique combinations of standard modifiers and scan codes before they are processed by the operating system. A keyboard map file associated with the application software converts the modified internal key codes received from the operating system to the characters, functions or commands to be identified with the original keystrokes.

This application is a continuation-in-part of provisional patent application No. ______, filed Jul. 14, 2000.

### BACKGROUND

Thin Client and Windows Based Terminal (WBT) systems are envisioned as a replacement for distributed computing systems in which a full-function PC operates on every desktop in the enterprise. While distributed systems may be networked to share data, storage, peripheral functions and some kinds of application programs, substantial stand-alone computing capability resides in each user's individual machine. Often this includes gigabytes of hard drive storage, diskette driver, CD-ROM and DVD ROM or other portable mass storage readers, and even portable mass storage writers. Thin Client and WBT systems contemplate a client-server architecture in which client units are PC's with fast processors and ample RAM, but without on-board permanent storage or input-output devices other than a keyboard, a mouse and a connection to a server or servers.

In addition to replacing networks of self-sufficient PC's, thin client networks can replace terminal-based systems. Many enterprises depending on centralized mainframe or midrange computers elect to replace hardware terminals with more flexible PCs on user desktops. Through use of emulation programs residing on a desktop PC or a connected server, the central computer communicates with the desktop units via the same I/O signals used with dedicated terminals. The remote user, meanwhile, has the flexibility of switching between the hosted application and locally stored or server-based personal productivity software, such as word processors, personal information managers or spreadsheet applications.

The current generation of IBM system-compatible terminal emulation PC hardware utilizes the PC architecture and an operating system designed to work with PC keyboards with 101 to 104 keys, whereas most IBM Mainframe and Midrange terminals are equipped with 122-key keyboards. Some users prefer the 122-key keyboard for continuity and simplicity of transition, thus maintaining productivity. However, the 122-key keyboard is not supported by the popular Windows operating systems, Windows 95, 98, NT, CE and 2000, prevalent in PC-based systems. The conventional approach is to support the 122-key keyboard directly from the emulation program at the application layer, bypassing the operating system layer. This approach requires the emulation program to be on the local PC, which is attached to the keyboard. The improved design of the present invention places, on the local PC, keyboard driver and filter files that convert the unsupported keyboard signals into a form recognized by the operating system. The operating system then transmits keystroke information to the emulator program, whether it is on the local PC or on a remote server.

### SUMMARY OF THE INVENTION

The present invention is addressed to the use of thin client or WBT systems in the terminal emulation environment. If a mainframe-terminal system is replaced with a client-server configuration, it is often desirable to make the changes as transparent as possible to the users. The former terminal unit, usually a monitor, control box and keyboard, is replaced by the monitor, logic unit and keyboard of the new unit. For the many whose legacy system terminals included a 122-key keyboard, implementation of a 122-key keyboard in the new system eases the transition.

The standard PC's and operating systems used in thin client and WBT systems are configured for 101-key keyboards, and although a 122-key keyboard can be plugged in, the operating system will ignore the scan code signals from unsupported keys. Corresponding keystrokes are not passed to the application program, resulting in dysfunction.

The present invention provides a solution by tricking the operating system into recognizing signals from the unsupported keys. The operating system's keyboard driver is superseded by a keyboard driver capable of processing all the scan codes from a 122-key keyboard. The driver transmits the scan codes to a filter, which passes on the standard scan codes and converts each non-standard scan code into a unique combination of scan codes representing combinations of 101-key keystrokes recognized by the operating system. A keyboard map accompanying the emulator then converts standard and combination keystroke codes from the operating system into the proper character or command codes for the application program.

### BRIEF DESCRIPTION OF THE DRAWINGS

FIG. 1 is the keyboard layout for a standard 101-key PC keyboard.

FIG. 2 is the keyboard layout for an IBM 3270 122-key keyboard.

FIG. 3 is the keyboard layout for an IBM 5250 keyboard for use with the AS/400 and I-Series minicomputer systems.

FIG. 4 is a scan code table for a 122-key keyboard in one embodiment of the invention.

FIG. 5 is a 122-key keyboard layout with each key uniquely designated.

FIG. 6 is a table showing the keyboard mapping of a 3270-style keyboard.

FIG. 7 is a table showing the keyboard mapping of a 5250-style keyboard.

### DETAILED DESCRIPTION

Modem keyboards output scan codes each time a key is pressed. Circuitry within the keyboard senses key depression and an on-board microprocessor generates a unique hexadecimal code on the output line corresponding to the location of the struck key. One code is generated when the key is pressed (the make code) and a different code is generated when the key is released (the break code). Make codes are necessary for all keys while break codes are essential only for modifier keys such as Shift, Control and Alt. Scan codes are converted by the terminal logic unit software to the characters, modifiers (Left Shift, Right Shift, Left Control, Right Control, Left Alt, Right Alt) or functions (e.g. Print, Help, Clear, Play, etc.) inscribed on the key. Some keyboards offer optional sets of scan codes selectable by the user, but the code for each key is always known.

The port on a terminal logic unit to which the keyboard is attached has a driver (which may be software or firmware) that recognizes and converts the incoming scan codes to either American Standard Code for Information Interchange (ASCII) or Extended Binary Coded Decimal Interchange Code (EBCDIC) characters. The ASCII and EBCDIC codes are then read as input data by the application program. When the terminal configuration is replaced by an emulation configuration, a personal computer sits on the desktop. The keyboard communicates with the personal computer, which must capture the keystrokes and send them to the emulator application program. The emulator may reside on the personal computer and communicate with the mainframe over a network, or the emulator may reside on a server and communicate with both the mainframe and one or more personal-computer-terminals over networks.

A number of different configurations of terminal emulation systems are possible, with varying equipment specifications, operating systems, network architectures and application programs. Many of these employ standard or modified PC units running one of the Microsoft Windows operating systems. One particularly efficient configuration is the thin client system, in which the local desktop unit is a minimally-configured PC having, for example, a 200 MHz processor, 64 Mb RAM, a flash memory of 8-16 Mb, standard ports (serial, parallel, USB and audio) and an ethernet connection to a server, which is in turn networked to the mainframe. The operating system on the PC is preferably Windows CE, while the server operating system may be Windows NT TS (Terminal Server), Windows 2000 Server, Citrix Winframe or Citrix Metaframe. The emulation software, an application program, may reside on the desktop unit or on the server, but would be most efficient on the server. While persons of ordinary skill in the art will readily grasp that many variants of equipment configuration, network architecture and operating system software are possible, the invention will be illustrated using this thin client configuration.

The standard PC running Windows CE is designed to work with a 101-key keyboard. In terminal emulation, however, it is desirable to attach the same type of keyboard used with the dedicated terminal, for consistency and ease of transition. Most of the popular mainframe and midrange systems, such as the IBM S/390 Mainframe or the IBM System 3/x or AS/400 midrange computers, use 122-key keyboards.

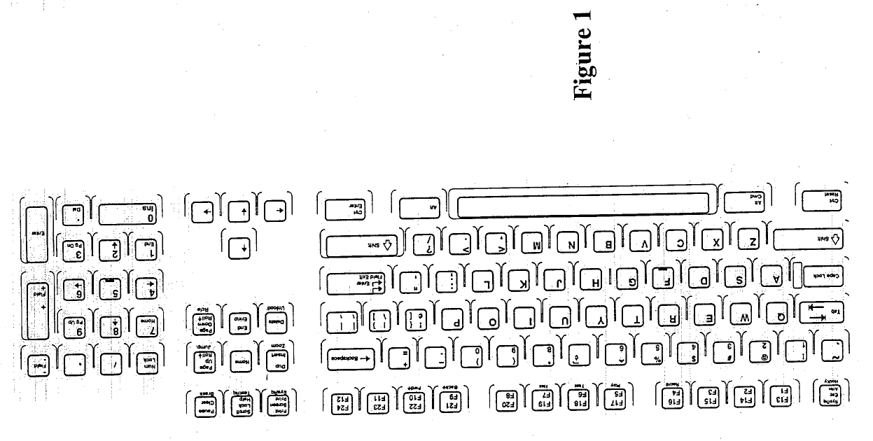

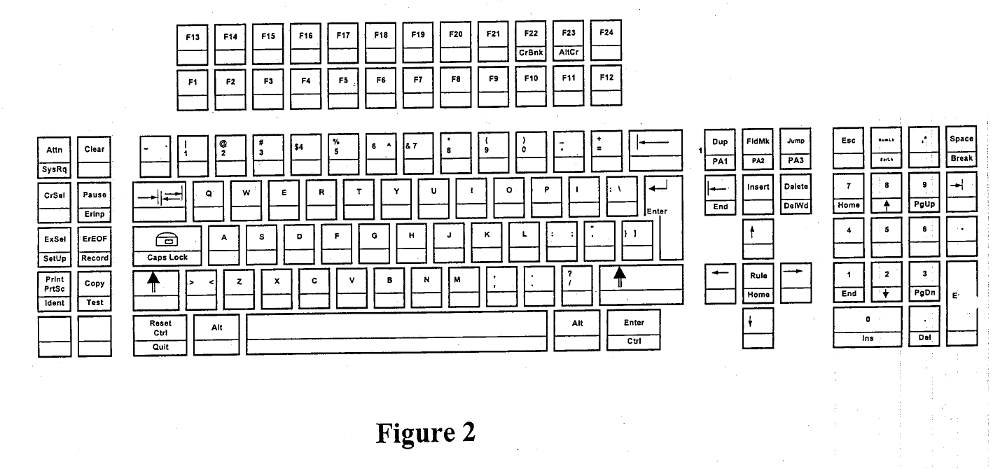

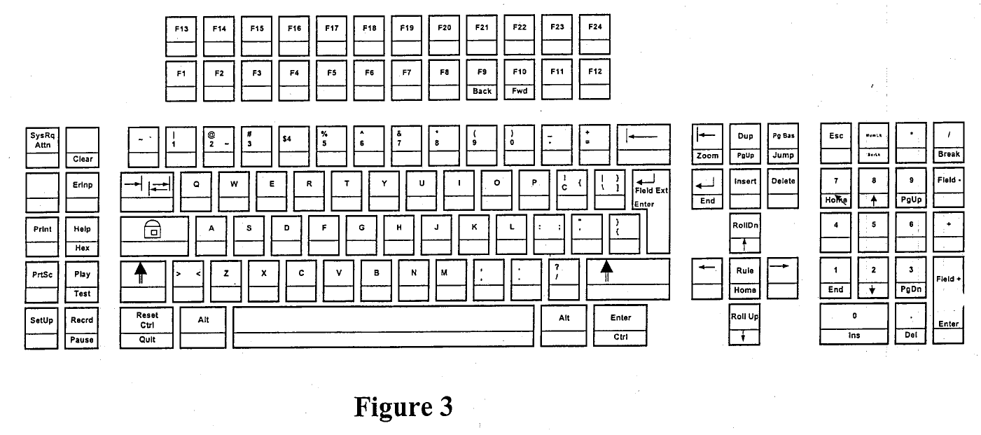

A typical 101-key keyboard is shown in FIG. 1, and two common versions of 122-key keyboards are shown in FIGS. 2 and 3. The 122-key keyboard is equipped with 24 Function keys while the PC 101 keyboard has only twelve. The 122-key keyboard also has two columns of keys to the left of the typewriter area, which are IBM host-specific function and editing keys. One embodiment of the invention uses a 122-key keyboard based on an IBM design dating back to the early 1980s and introduced with the 3270/PC for use with mainframe host computers. See FIG. 2. This design is a hybrid with the output of most keys being identical to a PC keyboard. Only 22 of the keys output unique scan codes, namely Function keys 13 to 24, 8 of the 10 keys on the left side of the keyboard, the key >< directly to the left of the Z key and the key immediately to the right of the Back Space key. This type of keyboard is supported by the Microsoft keyboard drivers in MS DOS, Windows 3X, and OS/2 Operating Systems but is not supported by the Microsoft keyboard drivers in Windows 95, 98, NT, CE or 2000.

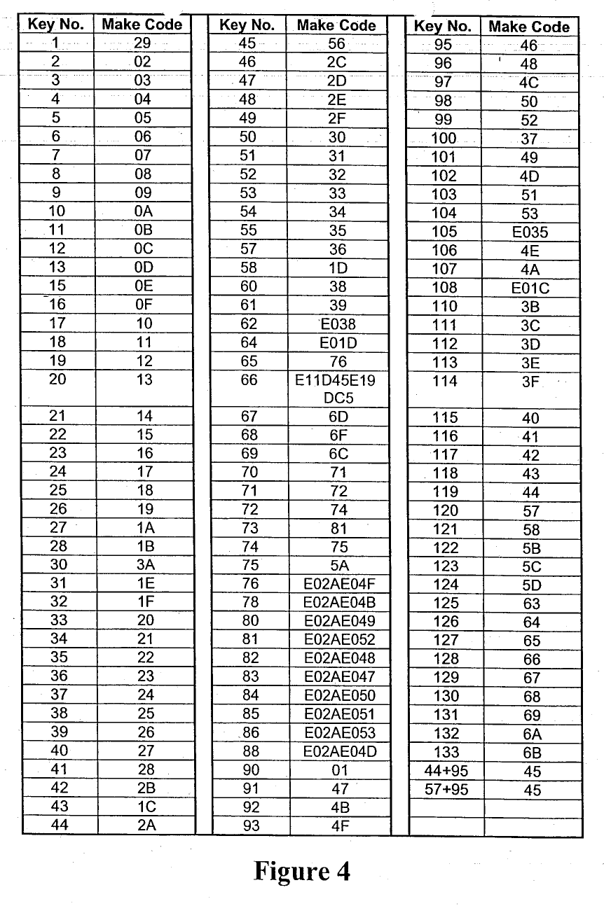

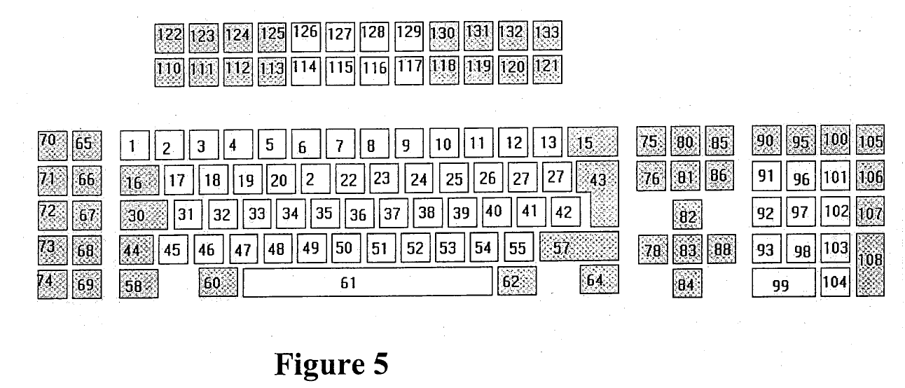

A representation of a 122-key keyboard, with each key uniquely numbered for identification, is shown in FIG. 4. The scan codes for the 3270/PC keyboard keys, as provided by the manufacturer, are shown with their corresponding key identifiers in FIG. 5.

In most thin client terminal emulation systems adapted to a 122-key keyboard, a new keyboard driver program, written in a conventional manner, supersedes the keyboard driver that comes with the operating system software. The driver intercepts every scan code before it is processed by the operating system and directs it to the emulator application, which is programmed to recognize the scan codes and process them for communication to the mainframe as ASCII or EBCIDIC data. This driver also passes to the operating system standard scan codes, i.e., those that are supported by the operating system, along with Windows Virtual Key codes (VK codes) corresponding to the scan codes, just as though they had been processed by the originally-supplied keyboard driver. The operating system, performing in a routine manner, transmits the VK codes to the thin terminal protocol agent software, which communicates them to the server.

This conventional approach to thin client terminal emulation allows server-based Windows applications to be run from the desktop. If the user inadvertently hits an unsupported key, it is ignored. The disadvantage is that the emulator application must be present on the desktop unit to process the keyboard input, and cannot be run from the server to which the unit is networked.

The present invention solves this problem with a combination of a keyboard driver and a filter. As in the conventional approach, a replacement keyboard driver intercepts all scan codes as they arrive from the keyboard. Standard scan codes, with associated VK codes, are passed to the operating system. Instead of sending the scan codes to the emulator application for recognition of the nonstandard scan codes, however, the scan codes are sent to a filter. Using a table look-up, the filter converts the nonstandard scan code to a combination of modifiers and standard 101 key codes, and passes the modified scan codes and associated modified VK codes to the operating system.

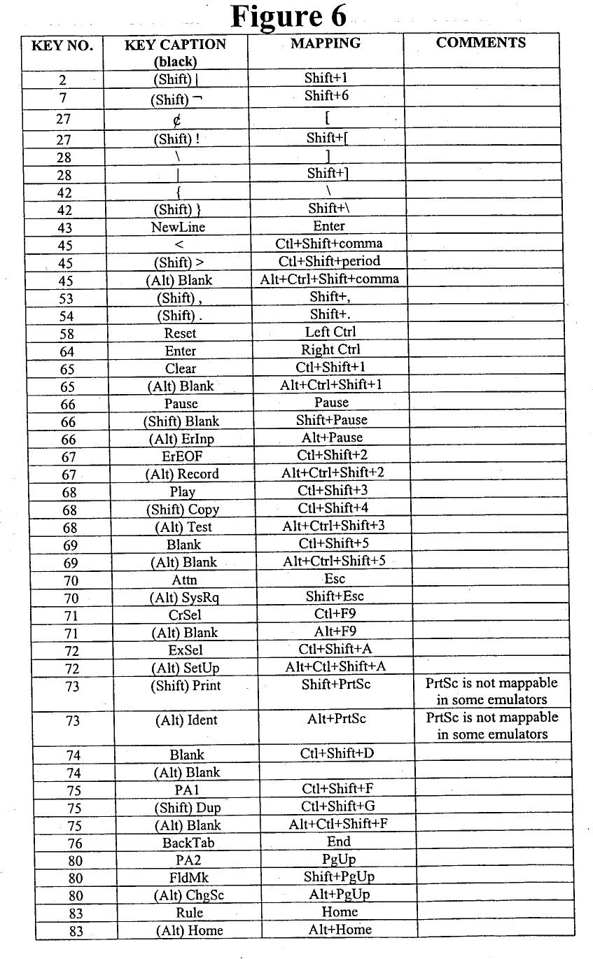

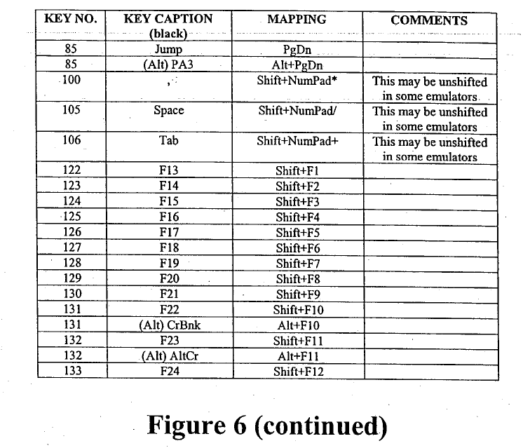

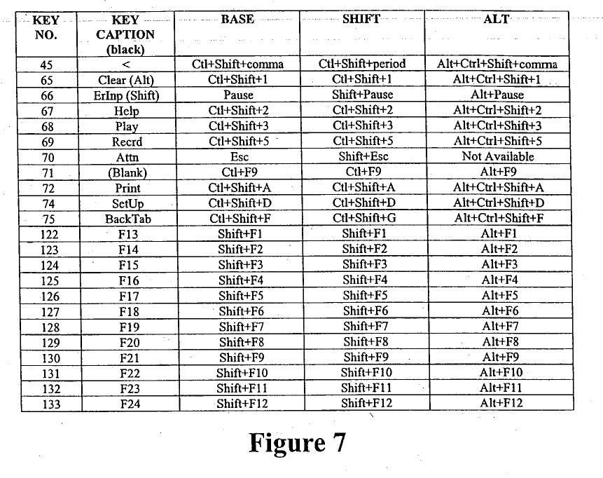

For example, the F14 key on the 122-key keyboard is a nonstandard key. In the filter, this key's scan code is converted to the supported scan codes for {Shift Down, F2, Shift Up} and sent, along with the VK codes for {Shift Down, F2, Shift Up}, to the operating system. The designated modified scan codes for the nonstandard keys of the 3270/PC keyboard of the instant embodiment are found at FIG. 6.

The operating system outputs the standard and modified VK codes. These can be directed to a local emulator application program, just as in conventional thin client terminal emulation, for conversion to communicate with the mainframe. FIG. 6 provides a keyboard map that can be associated in a conventional manner with the emulator software.

Alternatively, the standard and modified VK codes can be passed to the thin client protocol agent software and then communicated to a server. The server may host the emulator application software and connect to the mainframe, or may connect to a separate emulator server in turn connected to the mainframe. Of course, the keyboard map file must be associated with the emulation software wherever it is located. In this configuration, multiple operators may use a single copy of the emulator application software, enjoying the benefit of thin client system design. Server-hosted emulator application software cannot work in the conventional thin client terminal emulation arrangement because the Windows operating system on the server is designed to accept and transmit only VK codes as keyboard input signals. Thus, there is no way to communicate the raw scan codes to the emulator application through a network, and that emulator must reside on the desktop where it can intercept scan codes for direct processing.

The foregoing description uses a particular keyboard and operating system combination as an example, but it may readily be seen that many variations within the scope of the invention are available. One example is implementation of the IBM 5250-type keyboard, a 122-key keyboard commonly used with the AS/400 and I-Series midrange computers. FIG. 3 shows the 5250 keyboard layout, and FIG. 6 is a keyboard mapping file (showing the combinations for modified scan codes and modified VK codes) that may be used for the nonstandard keys.

Additionally, other local operating systems may be selected instead of Windows CE, and these do not necessarily have to be Windows-based. Any terminal emulation system in which an operating system that does not support all the scan codes from the keyboard must convert scan codes to internal key codes for use by networked applications will benefit from this invention. Nor do the illustrated modified scan codes constitute the only workable substitutes for nonstandard scan codes. Numerous alterations and modifications of the structure herein disclosed will suggest themselves to those skilled in the art. All such modifications which do not depart from the spirit of the invention are intended to be included within the scope of the appended claims.

1. A computer system having a logic unit with a central processor; an operating system program; at least one application program; a keyboard attached to a port on the logic unit wherein the keyboard transmits scan codes to the logic unit, at least one of which scan codes is not recognized by the operating system for processing and transmittal to the application program; a keyboard driver program that intercepts incoming scan codes from the keyboard and transmits them to a filter program which converts any unrecognized scan codes to unique combinations of scan codes recognized by the operating system, adds internal key codes associated with each recognized and unrecognized scan code, and transmits scan codes and internal key codes to the operating system; and a keyboard mapping program which associates each internal key codes with an originating keystrokes for use by the application program.

2. The system of claim 1 further including a network connection to a server and wherein the application program and the keyboard mapping program are on the server.

3. The system of claim 2 wherein the keyboard is a 122-key keyboard adapted for use with a mainframe or midrange computer terminal.

4. The system of claim 3 wherein the logic unit operating system is a Windows operating system and the internal key codes are virtual key codes.

5. The system of claim 3 wherein the application program is a terminal emulation program.

6. The system of claim 4 wherein the application program is a terminal emulation program.

7. The system of claim 1 wherein the keyboard driver program and the filter program are combined into a single program that intercepts incoming scan codes from the keyboard, converts any unrecognized scan codes to unique combinations of scan codes recognized by the operating system, adds internal key codes associated with each recognized and unrecognized scan code, and transmits scan codes and internal key codes to the operating system.

8. The system of claim 7 further including a network connection to a server and wherein the application program and keyboard mapping program are on the server.

9. The system of claim 8 wherein the keyboard is a 122-key keyboard adapted for use with a mainframe or midrange computer terminal.

10. The system of claim 9 wherein the logic unit operating system is a Windows operating system and the internal key codes are virtual key codes.

11. The system of claim 9 wherein the application program is a terminal emulation program.

12. The system of claim 10 wherein the application program is a terminal emulation program.

13. A method of using a keyboard in connection with a computer system having an operating system that does not recognize at least one scan code generated by the keyboard, comprising the steps of adding a keyboard driver and filter program that intercepts incoming scan codes before they are processed by the operating system, attaches internal key codes to scan codes recognized by the operating system, converts each unrecognized scan code to a unique combination of recognized scan codes and attaches internal key codes corresponding to said unique combination; transmitting the recognized scan codes and associated internal key codes and the unique combinations of keyboard scan codes and associated combinations of internal key codes to the operating system for regular processing; and adding a keyboard mapping program associated with an application program, which mapping identifies desired characters, functions and commands associated with the internal key codes generated by the filter program.

14. The method of claim 13 wherein the addition of a keyboard driver and filter program is replaced by the steps of adding a keyboard driver program and a filter program wherein the keyboard driver program intercepts incoming scan codes before they are processed by the operating system and transmits them, without first passing through the operating system, to the filter program, which attaches internal key codes to scan codes recognized by the operating system, converts each unrecognized scan code to a unique combination of recognized scan codes and attaches internal key codes corresponding to said unique combination, then transmitting the recognized scan codes and associated internal key codes and the unique combinations of keyboard scan codes and associated combinations of internal key codes to the operating system for regular processing.
